(19) United States
(12) Patent Application Publication
(10) Pub. No.: US 2015/0244318 A1
(43) Pub. Date: Aug. 27, 2015

(54) OSCILLATION CIRCUIT AND SEMICONDUCTOR INTEGRATED CIRCUIT DEVICE INCLUDING THE SAME

(71) Applicant: ALPS ELECTRIC CO., LTD., Tokyo (JP)

(72) Inventors: Junichi SAITO, Miyagi-ken (JP); Kimihiro NAKAO, Miyagi-ken (JP)

(21) Appl. No.: 14/603,189

(22) Filed: Jan. 22, 2015

(30) Foreign Application Priority Data
Feb. 21, 2014 (JP) 2014-032099

(51) Int. Cl. H03B 5/02

(52) U.S. Cl. CPC H03B 5/02

(57) ABSTRACT

When an external clock signal exceeding a power supply voltage is input to a first terminal, a voltage of a bulk of a P type MOS transistor becomes higher than a power supply voltage, but a current does not flow from the bulk of the P type MOS transistor to a first power supply line since a first diode is provided in a forward direction with respect to a direction of a current flowing from a first power supply line to the bulk of the P type MOS transistor. Therefore, it is possible to reliably prevent a reverse current from flowing from the first terminal to the first power supply line.

### CLAIM OF PRIORITY

This application claims benefit of Japanese Patent Application No. 2014-032099 filed on Feb. 21, 2014, which is hereby incorporated by reference.

### BACKGROUND OF THE INVENTION

1. Field of the Invention

The present invention relates to an oscillation circuit formed in a semiconductor integrated circuit device, and more particularly, to an oscillation circuit capable of oscillating using an oscillator and operating with an input clock signal.

2. Description of the Related Art

For example, an oscillation circuit illustrated in FIG. 7 is known as a circuit to which a crystal oscillator or a ceramic oscillator is connected to obtain a pulsed clock signal (for example, FIG. 9 in Japanese Unexamined Patent Application Publication No. 2002-246898). In the oscillation circuit illustrated in FIG. 7, an oscillator 53 and a resistor 52 are connected between an input and an output of an inverter circuit 51, and capacitors C54 and C55 are connected to the input and the output, respectively. In this circuit, when the oscillator 53 is not connected, a clock signal can be input from the outside to a circuit in an IC by supplying a clock signal CLK_EX generated by an external oscillator (not illustrated) to the inverter circuit 51, as illustrated in FIG. 8, and the circuit is generally widely used in an IC such as a CPU. A voltage level of the clock signal CLK_EX supplied from the outside is the same as a power supply voltage level in the IC.

A withstand voltage of a device tends to decrease due to miniaturization of a semiconductor manufacturing process. Since a core logic such as a CPU having a large circuit scale is produced through a micro-process, the withstand voltage is generally low. In contrast, in an interface unit with the outside of an IC chip, a signal is often exchanged at a voltage level higher than a withstand voltage of a core logic.

FIG. 9 is a diagram illustrating a case in which a power supply voltage VDD_EX for an interface with the outside is supplied to an oscillation circuit. In an example of FIG. 9, a power supply line of the power supply voltage VDD_EX used for an interface with the outside of an IC chip is connected to a power supply pad 59 of the IC. Generally, since a relatively high current is necessary for an interface with the outside of the IC chip, the dedicated power supply pad 59 is provided. The external power supply voltage VDD_EX input at this power supply pad is supplied to an inverter circuit 51 of the oscillation circuit. The external power supply voltage VDD_EX is higher than a power supply voltage VDD of a core logic 50. A voltage level of the signal input or output in the core logic 50 is converted by level shift circuits 61 and 62.

FIG. 10 is a diagram illustrating a case in which a power supply voltage VDD_EX for an interface with the outside is supplied to an oscillation circuit, and illustrates a case in which a clock signal of the oscillation circuit is supplied to a core logic 50 for control of an analog circuit 64. As illustrated in FIG. 10, there is the analog circuit 64 that outputs an analog signal Aout, and when the analog circuit is a main function of an IC, the core logic 50 often has a function of controlling the analog circuit 64. The core logic 50 usually controls the analog circuit 64 based on a digital control signal Sd input from the outside of the IC. Therefore, a pad 60 for connecting a communication line for transferring the control signal Sd is provided in the IC. When the analog circuit 64 is controlled using the communication line, a power supply line for an external power supply is connected to a dedicated power supply pad 59 as a power supply for the communication line.

In the circuit illustrated in FIG. 10, the power supply for the communication line described above may be disconnected. For example, when adjustment of the analog circuit 64 is performed, a cable including the power supply line for communication and the communication line is connected to a device using a connector or the like, and when the adjustment ends, the connector is removed. In this case, in the circuit illustrated in FIG. 10, there is a problem in that the power supply voltage VDD_EX is not supplied to the oscillation circuit such that the oscillation circuit cannot be operated.

In order to solve this problem, in a circuit illustrated in FIG. 11, the same power supply voltage VDD as that for a core logic 50 is supplied to an oscillation circuit. In this case, even when an external power supply line and a communication line are not connected, the oscillation circuit operates. However, when an oscillator is removed and a clock signal is input from the outside of an IC as illustrated in FIG. 11, a voltage level thereof is limited to a power supply voltage level (VDD) for an internal core logic. As described above, a voltage level of a signal used in the outside of the IC is often higher than the power supply voltage VDD of the core logic 50, and cannot be usually input to the IC as it is. That is, there is a problem in that the voltage level should be converted by a level shift circuit, and an additional circuit should be provided.

FIG. 12 is a diagram illustrating a case in which a current flows backward to a power supply in an IC when a clock signal CLK_EX supplied from the outside exceeds an internal power supply voltage VDD. Further, FIG. 13 is a diagram illustrating a structure of a P type MOS transistor 65 constituting an inverter circuit 51, and illustrates a case in which a current flows backward from a drain of the P type MOS transistor 65 to a power supply in an IC via a bulk. There is a problem in that, when a voltage higher than a power supply voltage VDD of a core logic 50 in the IC is applied to an input of an inverter circuit 51, a current flows backward to the power supply in the IC via a feedback resistor 52 and a P type MOS transistor 65, as illustrated in FIGS. 12 and 13.

### SUMMARY OF THE INVENTION

The present invention provides an oscillation circuit capable of preventing a reverse current from flowing to a power supply even when a clock signal exceeding a power supply voltage is input, and a semiconductor integrated circuit including the oscillation circuit.

According to a first aspect of the present invention, there is provided an oscillation circuit including: a first inverter circuit; a feedback circuit configured to feed back a signal from an output to an input of the first inverter circuit; a first terminal connected to the input of the first inverter circuit; and a second terminal connected to the output of the first inverter circuit. The first inverter circuit includes at least one P type MOS transistor provided in a path that connects a first power supply line supplying a power supply voltage and the output; and a first diode provided in a forward direction with respect to a direction of a current flowing from the first power supply line to the bulk of the P type MOS transistor in a path that connects the bulk with the first power supply line. In the oscillation circuit, an oscillator is capable of being connected between the first terminal and the second terminal, and a clock signal is capable of being input to the first terminal.

According to the above-described configuration, when a clock signal exceeding the power supply voltage is input to the first terminal, the voltage of the bulk of the P type MOS transistor becomes higher than the power supply voltage, but a current does not flow from the bulk of the P type MOS transistor to the first power supply line since the first diode is provided in the forward direction with respect to the direction of the current flowing from the first power supply line to the bulk of the P type MOS transistor. Therefore, a reverse current does not flow from the first terminal to the first power supply line.

Preferably, the oscillation circuit may further include a second inverter circuit to which a power supply voltage is supplied from the first power supply line, to which a signal is input from the input or the output of the first inverter circuit, and that outputs a clock signal according to the input signal.

Preferably, the first inverter circuit may include a second diode provided in a forward direction with respect to a direction of a current flowing from a second power supply line to the bulk of the P type MOS transistor in a path that connects the second power supply line with the bulk, the second power supply line supplying a power supply voltage higher than that of the first power supply line.

According to the above-described configuration, when a clock signal exceeding the power supply voltage of the second power supply line is input to the first terminal, a voltage of the bulk of the P type MOS transistor becomes higher than the power supply voltage of the second power supply line, but a current does not flow from the bulk of the P type MOS transistor to the second power supply line since the second diode is provided in the forward direction with respect to the direction of the current flowing from the second power supply line to the bulk of the P type MOS transistor. Further, since the first diode is provided, the current does not flow from the bulk of the P type MOS transistor to the first power supply line. Therefore, a reverse current does not flow from the first terminal to the first power supply line and the second power supply line.

Preferably, a plurality of second diodes may be provided in series in the path that connects the second power supply line with the bulk of the P type MOS transistor.

Accordingly, since the voltage of the bulk decreases with respect to a source of the P type MOS transistor, influence of substrate bias effect in the P type MOS transistor is reduced.

According to a second aspect of the present invention, there is a provided a semiconductor integrated circuit device, including: an oscillation circuit according to the first aspect; and a digital circuit that operates in synchronization with a clock signal output from the oscillation circuit.

According to the present invention, even when a clock signal exceeding the power supply voltage is input, a reverse current can be prevented from flowing to the power supply.

### BRIEF DESCRIPTION OF THE DRAWINGS

FIG. 1 is a diagram illustrating an example of a configuration of a semiconductor integrated circuit device according to a first embodiment and illustrates a case in which an oscillator is connected to an oscillation circuit;

FIG. 2 illustrates a case in which an external clock signal is input to an oscillation circuit of a semiconductor integrated circuit device according to the first embodiment;

FIG. 3 is a diagram illustrating a structure of a P type MOS transistor in an inverter circuit illustrated in FIG. 2 and a path of a reverse current;

FIG. 4 is a diagram illustrating an example of a configuration of a semiconductor integrated circuit device according to a second embodiment and illustrates a case in which an oscillator is connected to an oscillation circuit;

FIG. 5 illustrates a case in which an external clock signal is input to an oscillation circuit of the semiconductor integrated circuit device according to the second embodiment;

FIG. 6 is a diagram illustrating a structure of a P type MOS transistor in an inverter circuit illustrated in FIG. 5 and a path of a reverse current;

FIG. 7 is a diagram illustrating an oscillation circuit in the related art and illustrates a case in which an oscillator for an oscillation operation is connected;

FIG. 8 is a diagram illustrating an oscillation circuit in the related art and illustrates a case in which a clock signal is input from an external oscillator;

FIG. 9 is a diagram illustrating a case in which a power supply voltage for an interface with the outside is supplied to an oscillation circuit;

FIG. 10 is a diagram illustrating a case in which a power supply voltage for an interface with the outside is supplied to an oscillation circuit and illustrates the case in which a clock signal of the oscillation circuit is supplied to a core logic for control of an analog circuit;

FIG. 11 is a diagram illustrating an example of an oscillation circuit to which a power supply voltage in an IC is supplied;

FIG. 12 is a diagram illustrating a current flowing backward to a power supply in an IC when a clock signal supplied from the outside exceeds an internal power supply voltage; and

FIG. 13 is a diagram illustrating a structure of a P type MOS transistor constituting an inverter circuit and illustrates that a current flows backward from a drain of a P type MOS transistor to an internal power supply via a bulk.

### DESCRIPTION OF THE PREFERRED EMBODIMENTS

### First Embodiment

Hereinafter, a first embodiment of the present invention will be described with reference to the drawings.

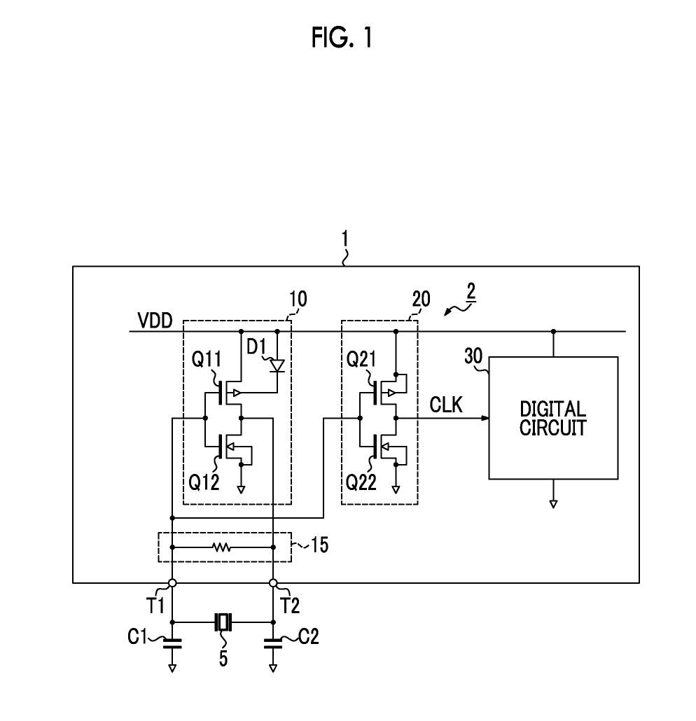

FIG. 1 is a diagram illustrating an example of a configuration of a semiconductor integrated circuit device 1 according to the first embodiment. The semiconductor integrated circuit device 1 illustrated in FIG. 1 includes an oscillation circuit 2 that outputs a clock signal CLK, and a digital circuit 30 that operates in synchronization with the clock signal CLK. The oscillation circuit 2 includes a first inverter circuit 10, a feedback circuit 15, a first terminal T1 connected to an input of the first inverter circuit 10, a second terminal T2 connected to the output of the first inverter circuit 10, and a second inverter circuit 20.

The first inverter circuit 10 includes, for example, a P type MOS transistor Q11, an N type MOS transistor Q12, and a first diode D1, as illustrated in FIG. 1.

A source of the P type MOS transistor Q11 is connected to a power supply line (may be hereinafter referred to as a “first power supply line”) that supplies a power supply voltage VDD, a drain thereof is connected to a drain of the N type MOS transistor Q12 and the second terminal T2, a gate thereof is connected to a gate of the N type MOS transistor Q12 and the first terminal T1, and a bulk (N well) thereof is connected to the first power supply line via the first diode D1. A source and a bulk (P well) of the N type MOS transistor Q12 are connected to a ground.

The first diode D1 is provided in a forward direction with respect to a direction of a current flowing from the first power supply line for the power supply voltage VDD to the bulk of the P type MOS transistor Q11 in a path that connects the bulk to the first power supply line. That is, an anode of the first diode D1 is connected to the first power supply line, and a cathode of the first diode D1 is connected to the bulk of the P type

MOS transistor Q11.

The feedback circuit 15 is a circuit that feeds back a signal from the output to the input of the first inverter circuit 10, and includes a resistor in the example of FIG. 1.

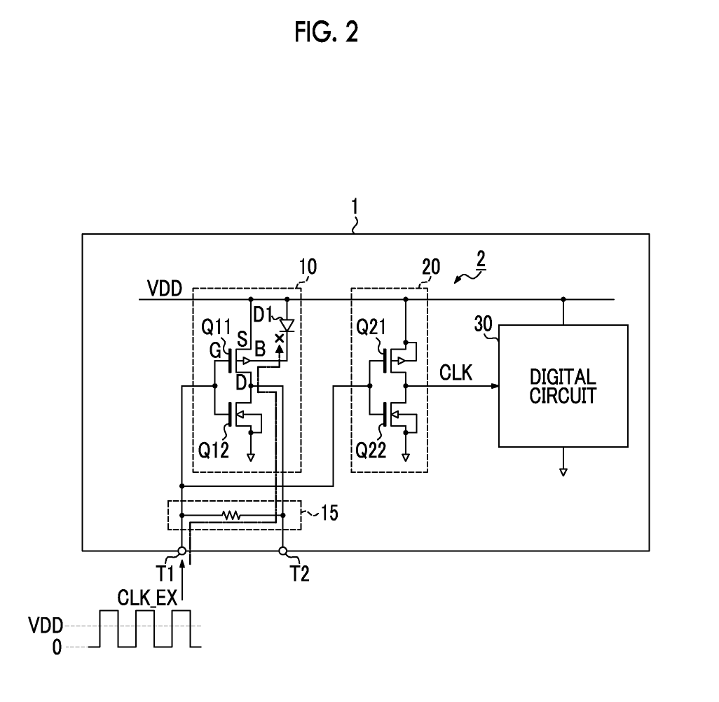

The second inverter circuit 20 includes, for example, a P type MOS transistor Q21 and an N type MOS transistor Q22, as illustrated in FIG. 2.

A source and a bulk (N well) of the P type MOS transistor Q21 are connected to the first power supply line, a drain thereof is connected to a drain of the N type MOS transistor Q22, and a gate thereof is connected to a gate of the N type MOS transistor Q22 and the first terminal T1. A source and a bulk (P well) of the N type MOS transistor Q22 are connected to the ground. A clock signal CLK is output from a node of connection of the drain of the P type MOS transistor Q21 with the drain of the N type MOS transistor Q22.

The digital circuit 30 is a circuit that processes a digital signal in synchronization with the clock signal CLK of the oscillation circuit 2, and operates based on the same power supply voltage VDD as the oscillation circuit 2.

In the example of FIG. 1, an oscillator 5, such as a crystal oscillator or a ceramic oscillator, and capacitors C1 and C2 are connected to the first terminal T1 and the second terminal T2. The oscillator 5 is connected between the first terminal T1 and the second terminal T2. The capacitor C1 is connected between the first terminal T1 and the ground, and the capacitor C2 is connected between the second terminal T2 and the ground.

FIG. 2 is a diagram illustrating a case in which an external clock signal CLK_EX is input to an oscillation circuit 2 of a semiconductor integrated circuit device 1 according to this embodiment. In an example of FIG. 2, an external clock signal CLK_EX generated by an oscillator (not illustrated) is input to a first terminal T1 instead of the oscillator 5 and the capacitors C1 and C2 connected to the external terminals T1 and T2.

Here, an operation of the oscillation circuit 2 having the above-described configuration will be described.

When the oscillator 5 and the capacitors C1 and C2 are connected to the external terminals T1 and T2 (FIG. 1), the oscillation circuit 2 oscillates at a frequency according to a natural frequency of the oscillator 5 and capacitance of the capacitors C1 and C2. In an oscillation state, an analog oscillation signal generated in the input of the first inverter circuit 10 is converted into a pulsed clock signal CLK in a second inverter circuit 20.

A bulk of a P type MOS transistor Q11 in the first inverter circuit 10 is connected to the first power supply line via a first diode D1. Since the first diode D1 is provided in a forward direction with respect to a direction of a current flowing from the first power supply line to the bulk, a voltage of the bulk of the P type MOS transistor Q11 is determined to be a voltage close to the power supply voltage VDD. Accordingly, the P type MOS transistor Q11 operates normally as a transistor that controls a channel between a source connected to the first power supply line and a drain depending on a gate voltage. Therefore, even when the first diode D1 is provided, the first inverter circuit 10 operates normally, and the oscillation circuit 2 oscillates.

On the other hand, when the external clock signal CLK_EX is input to the first terminal T1 as illustrated in FIG. 2, the oscillation circuit 2 does not oscillate. The external clock signal CLK_EX input to the first terminal T1 is input to the second inverter circuit 20 as it is, and a signal obtained by inverting the external clock signal CLK_EX is output from the second inverter circuit 20 as a clock signal CLK.

When a voltage level of the external clock signal CLK_EX becomes higher than the power supply voltage VDD, the voltage of the bulk of the P type MOS transistor Q11 becomes higher than the power supply voltage VDD. However, since the first diode D1 is provided between the bulk and the first power supply line, a reverse current illustrated by an alternating long and short dashed line in FIG. 2 is blocked by the first diode D1.

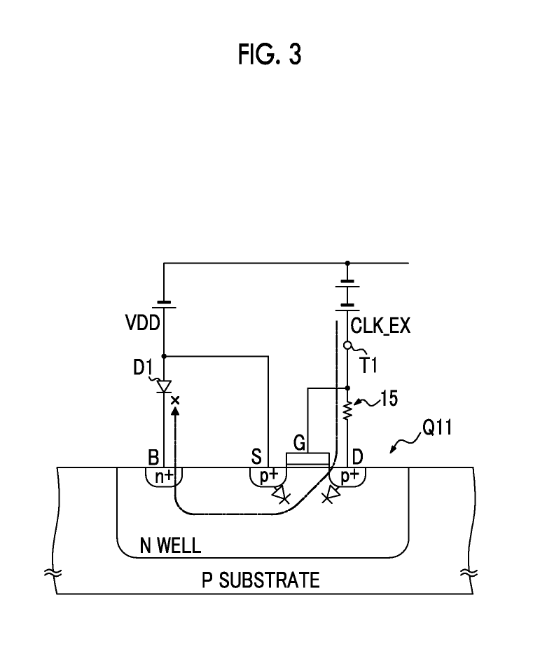

FIG. 3 is a diagram illustrating a structure of the P type MOS transistor Q11 in the inverter circuit 10 illustrated in FIG. 2 and a path for the reverse current.

In an example of FIG. 3, an N type diffusion region (an N well and a bulk) is formed in a surface of a P type substrate, and a P type diffusion region (P+) that is a source and a P type diffusion region (P+) that is a drain are formed on the inner side of the N well. Further, a gate electrode is formed via an insulation film on a channel region interposed between the two P type diffusion regions (P+). An N type diffusion region (N+) which connects the cathode of the first diode D1 with the N well (bulk) is formed in a surface of the N well.

A parasitic diode is formed in a border between the drain and the N well (bulk) and a border between the source and the N well (bulk). As illustrated by an alternating long and short dashed line in FIG. 3, when the external clock signal CLK_EX exceeding the power supply voltage VDD is input from the first terminal T1, the parasitic diode existing in the border between the drain and the N well (bulk) becomes a path for the reverse current. When the voltage of the first terminal T1 becomes higher than the power supply voltage VDD, the parasitic diode existing in the border between the drain and the N well (bulk) is conducted, and the voltage of the N well (bulk) becomes higher than the power supply voltage VDD. Here, since the reverse voltage is applied to the first diode D1 provided between the N well (bulk) and the first power supply line, a current does not flow to the first diode D1. Therefore, a reverse current from the first terminal T1 to the first power supply line is blocked by the first diode D1.

As described above, with the oscillation circuit 2 according to this embodiment, when the external clock signal CLK_EX exceeding the power supply voltage VDD is input to the first terminal T1, the voltage of the bulk of the P type MOS transistor Q11 becomes higher than the power supply voltage VDD, but the current does not flow from the bulk of the P type MOS transistor Q11 to the first power supply line since the first diode D1 is provided in the forward direction with respect to the direction of the current flowing from the first power supply line to the bulk of the P type MOS transistor Q11. Therefore, it is possible to reliably prevent a reverse current from flowing from the first terminal T1 to the first power supply line.

Further, with the oscillation circuit 2 according to this embodiment, when the voltages of the first terminal T1 and the second terminal T2 do not exceed the power supply voltage VDD of the first power supply line, the voltage of the bulk of the P type MOS transistor Q11 is determined to be the voltage close to the power supply voltage VDD, and the P type MOS transistor Q11 operates normally. Therefore, when the oscillator 5 is connected between the first terminal T1 and the second terminal T2, the first inverter circuit 10 including the P type MOS transistor Q11 can normally operate and the clock signal CLK can be generated.

Further, with the oscillation circuit 2 according to this embodiment, since the oscillation circuit 2 operates with the power supply voltage VDD in the semiconductor integrated circuit 1, it is possible to generate the clock signal CLK even when the external power supply voltage different from the power supply voltage VDD is not supplied.

Further, with the oscillation circuit 2 according to this embodiment, by providing the second inverter circuit 20 to which a signal is input from the first terminal T1, it is possible to convert the analog oscillation signal into a pulsed clock signal CLK with a sharp edge even when the oscillator 5 is connected between the first terminal T1 and the second terminal T2 to cause oscillation and the external clock signal CLK_EX is input from the first terminal T1.

### Second Embodiment

Next, a second embodiment of the present invention will be described.

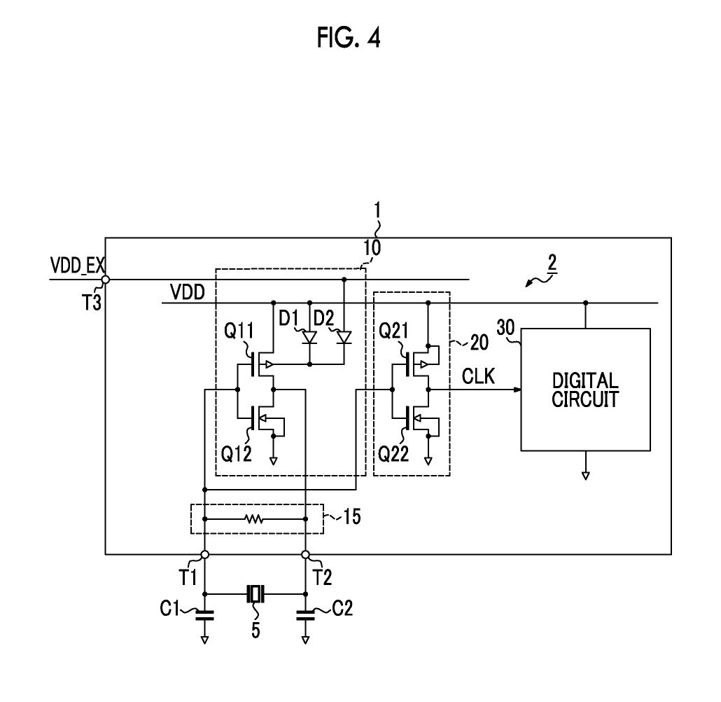

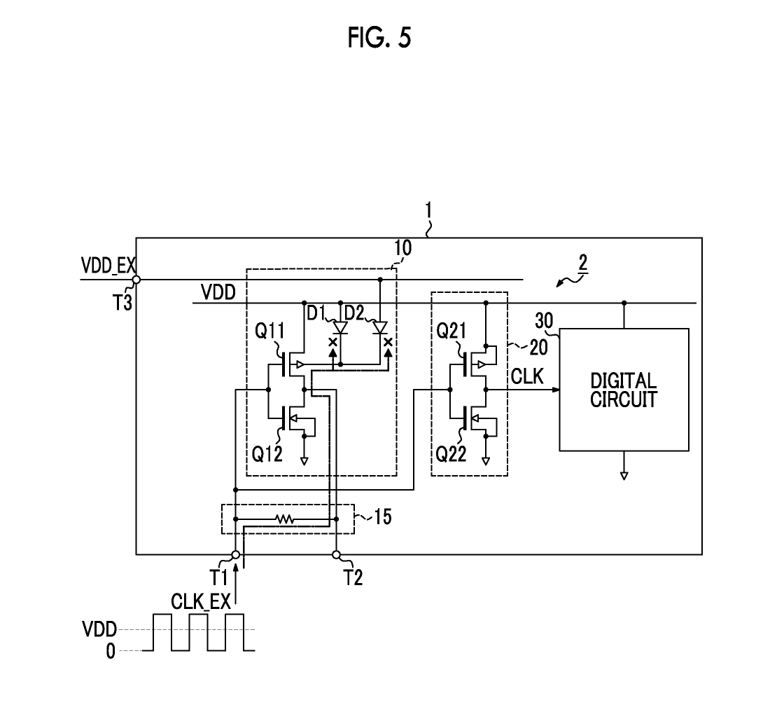

FIG. 4 is a diagram illustrating an example of a configuration of a semiconductor integrated circuit device 1 according to a second embodiment, and illustrates a case in which an oscillator 5 is connected to an oscillation circuit 2. Further, FIG. 5 illustrates a case in which an external clock signal CLK_EX is input to the oscillation circuit 2 of the semiconductor integrated circuit device 1 according to this embodiment.

In the semiconductor integrated circuit device 1 illustrated in FIGS. 4 and 5, a terminal T3 for input of an external power supply voltage VDD_EX is provided in the semiconductor integrated circuit device 1 illustrated in FIGS. 1 and 2, and a second diode D2 is provided between a power supply line (hereinafter also referred to as a “second power supply line”) that supplies the external power supply voltage VDD_EX and a bulk of a P type MOS transistor Q11. Other configurations are the same as those of the semiconductor integrated circuit device 1 illustrated in FIGS. 1 and 2.

The second diode D2 is provided in a forward direction with respect to a direction of a current flowing from the second power supply line to the bulk of the P type MOS transistor Q11 in a path that connects the second power supply line with the bulk.

When the oscillator 5 and capacitors C1 and C2 are connected to a first terminal T1 and a second terminal T2 to cause oscillation (FIG. 4), the first terminal T1 and the second terminal T2 are at a voltage that does not exceed the power supply voltage VDD or the external power supply voltage VDD_EX. Here, when the external power supply voltage VDD_EX is higher than the power supply voltage VDD, a voltage of the bulk of the P type MOS transistor Q11 is determined to be a voltage close to the external power supply voltage VDD_EX by the second diode D2 connected to the second power supply line. Therefore, the P type MOS transistor Q11 operates normally as a transistor that controls a channel between a source connected to the first power supply line and a drain depending on a gate voltage. Therefore, even when the second diode D2 is provided, the first inverter circuit 10 operates normally, and the oscillation circuit 2 oscillates.

On the other hand, when the external clock signal CLK_EX is input to the first terminal T1 (FIG. 5), if a voltage level of the external clock signal CLK_EX becomes higher than the external power supply voltage VDD_EX, a voltage of the bulk of the P type MOS transistor Q11 becomes higher than the external power supply voltage VDD_EX. However, since the second diode D2 is provided between the bulk and the second power supply line, a reverse current illustrated by an alternating long and short dashed line illustrated in FIG. 5 is blocked by the second diode D2.

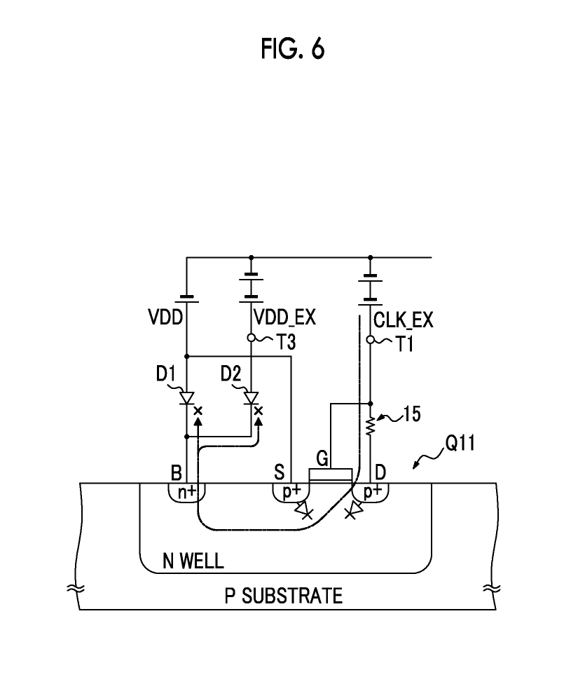

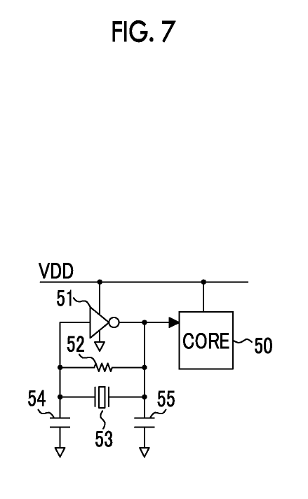

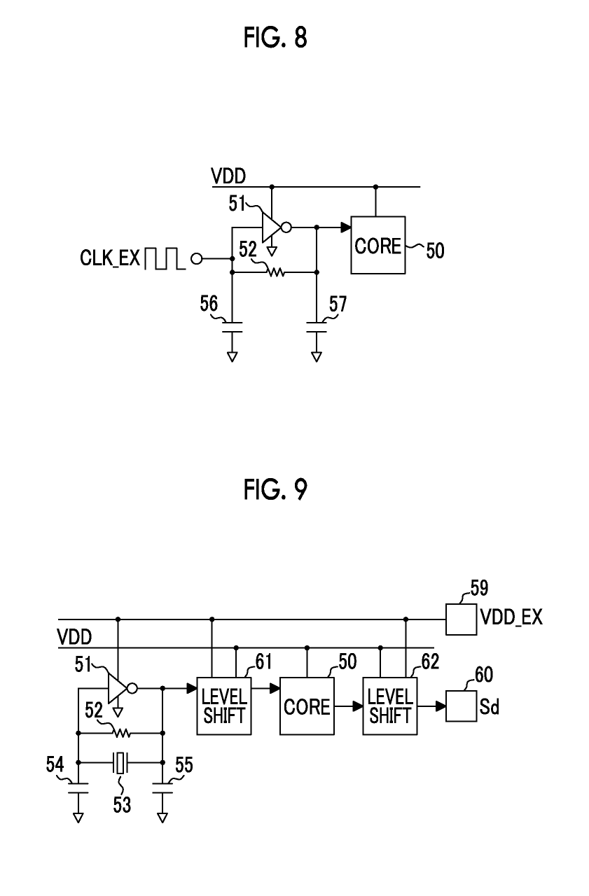

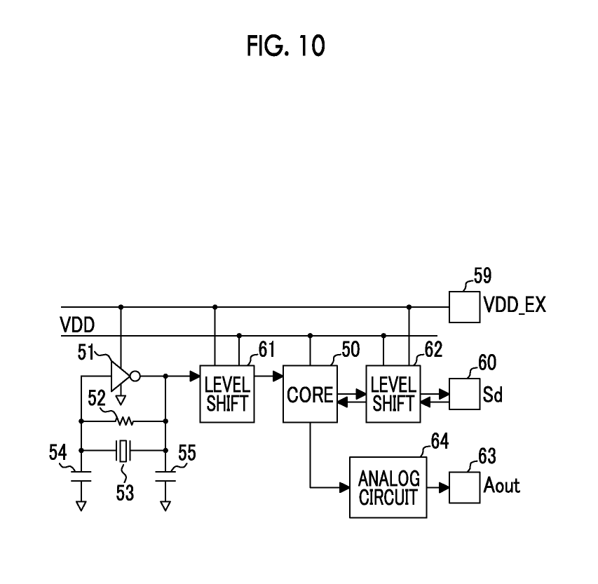

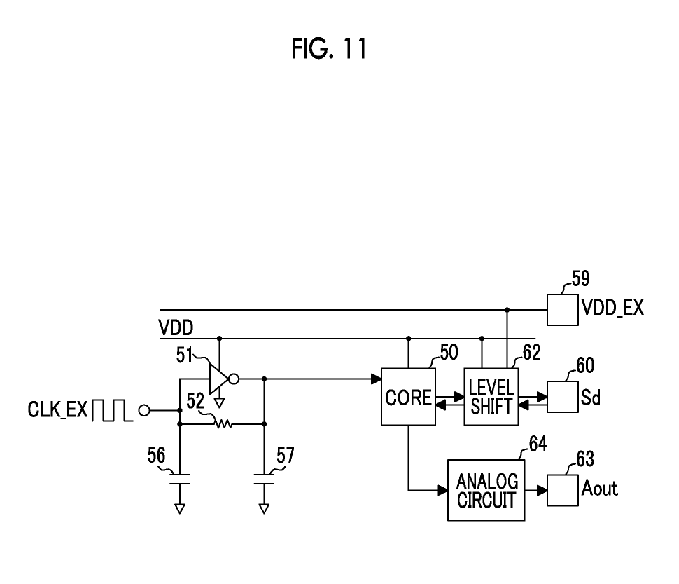

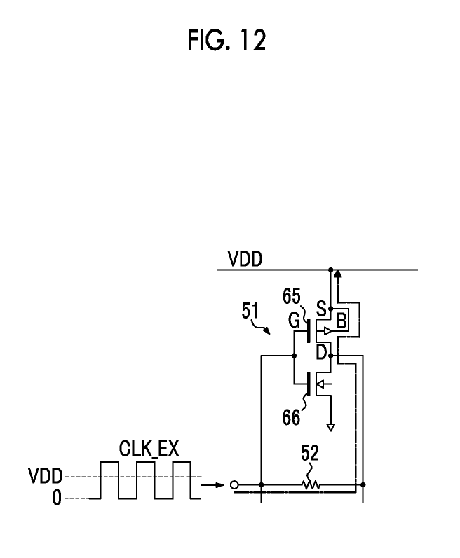

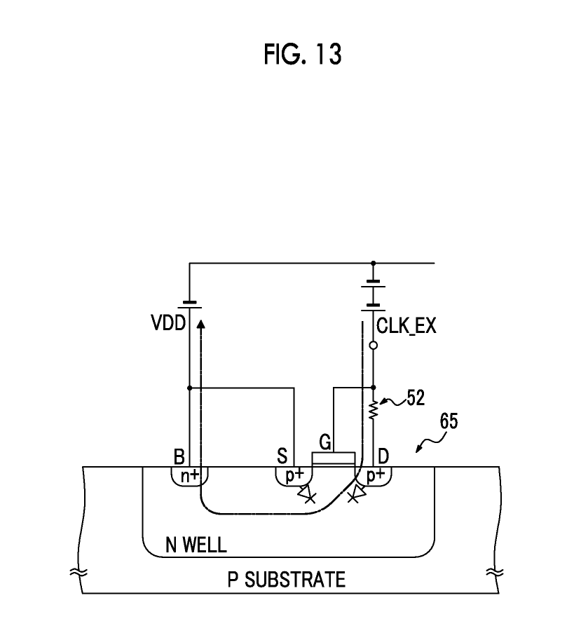

FIG. 6 is a diagram illustrating a structure of the P type MOS transistor Q11 in the inverter circuit 10 illustrated in FIG. 5 and a path for the reverse current.

When the external clock signal CLK_EX exceeding the external power supply voltage VDD_EX is input from the first terminal T1 as illustrated by an alternating long and short dashed line in FIG. 6, a parasitic diode existing in a border between a drain and an N well (bulk) is conducted, and a voltage of the N well (bulk) becomes higher than the external power supply voltage VDD_EX. However, since the reverse voltage is applied to the second diode D2 provided between the N well (bulk) and the second power supply line, a current does not flow in the second diode D2 and a reverse current from the first terminal T1 to the second power supply line is prevented.

As described above, with the oscillation circuit 2 according to this embodiment, when the external clock signal CLK_EX exceeding the external power supply voltage VDD_EX is input to the first terminal T1, the voltage of the bulk of the P type MOS transistor Q11 becomes higher than the external power supply voltage VDD_EX and a reverse voltage is applied to the second diode D2. Accordingly, a current does not flow to the first diode D1. Therefore, it is possible to reliably prevent a reverse current from flowing from the first terminal T1 to the first power supply line.

Further, even when the bulk of the P type MOS transistor Q11 becomes a voltage exceeding the power supply voltage VDD, since the first diode D1 is provided between the bulk and the first power supply line, a current flows from the second power supply line to the first power supply line via the bulk, and a reverse current does not flow from the first terminal T1 to the first power supply line via the bulk.

Further, the present invention is not limited to the embodiments described above and includes various variations.

While the input of the second inverter circuit 20 is connected to the first terminal T1 in the embodiment described above, the present invention is not limited thereto. In other embodiments of the present invention, the input of the second inverter circuit 20 may be connected to the second terminal T2. In this case, an oscillation signal output from the first inverter circuit 10 (or, a signal obtained by inverting the external clock signal CLK_EX in the first inverter circuit 10) can be input to the second inverter circuit 20 to generate a pulsed clock signal CLK depending on the signal.

While one second diode D2 is provided between the bulk of the P type MOS transistor Q11 and the second power supply line in the embodiment described above, a plurality of second diodes D2 may be provided in series in other embodiments of the present invention.

When the external power supply voltage VDD_EX is higher than the power supply voltage VDD, if the voltage of the bulk of the P type MOS transistor Q11 becomes a voltage close to the external power supply voltage VDD_EX by the second diode D2, the voltage of the bulk with respect to the source becomes high, and a threshold voltage of the P type MOS transistor Q11 increases due to a substrate bias effect. Since an operation property of the P type MOS transistor Q11 is changed if the threshold voltage becomes too high, the oscillation is likely to be unstable. By providing the plurality of second diodes D2 in series, the voltage of the bulk of the P type MOS transistor Q11 decreases and a voltage difference between the source and the bulk decreases, and thus, it is possible to reduce the influence of the substrate bias effect described above.

It should be understood by those skilled in the art that various modifications, combinations, sub-combinations and alterations may occur depending on design requirements and other factors insofar as they are within the scope of the appended claims of the equivalents thereof.

1. An oscillation circuit comprising:
a first inverter circuit having a first input and a first output;
a feedback circuit configured to feed back a signal from the first output to the first input;
a first terminal connected to the first input; and
a second terminal connected to the first output wherein the first inverter circuit includes:
at least one P type MOS transistor provided between the first output and a first power supply line supplying a first power supply voltage, a current flowing from the first power supply line to a bulk of the P type MOS transistor; and
a first diode provided between the first power supply line and the bulk of the P type MOS transistor in a forward direction with respect to a direction of the current,
and wherein the first terminal and the second terminal are configured to connect an oscillator therebetween, and the first terminal is configured to receive an external clock signal when the oscillator is not connected thereto.

2. The oscillation circuit according to claim 1, further comprising:
a second inverter circuit to which the first power supply voltage is supplied from the first power supply line, the second inverter having a second input configured to receive an input signal from the first input or the first output of the first inverter circuit, and a second output configured to output a clock signal according to the input signal.

3. The oscillation circuit according to claim 1, wherein the first inverter circuit further includes:
a second diode provided between a second power supply line and the bulk of the P type MOS transistor in a forward direction with respect to a direction of a current flowing from the second power supply line to the bulk of the P type MOS transistor, the second power supply line supplying a second power supply voltage higher than the first power supply voltage.

4. The oscillation circuit according to claim 3,
wherein a plurality of second diodes are provided in series between the second power supply line and with the bulk of the P type MOS transistor.

5. A semiconductor integrated circuit device, comprising:
the oscillation circuit according to claim 1; and
a digital circuit that operates in synchronization with a clock signal output from the oscillation circuit.

6. The oscillation circuit according to claim 1, wherein the external clock signal has a voltage level higher than the first power supply voltage.

7. The oscillation circuit according to claim 1, wherein the first diode prevents a current from flowing from the first terminal though the feedback circuit through the first output to the first power supply line when the external clock signal has a voltage level higher than the first power supply voltage.

8. The oscillation circuit according to claim 1, further comprising:
a second inverter circuit to which the first power supply voltage is supplied from the first power supply line, the second inverter having a second input configured to receive an input signal from the first input or the first terminal, and a second output configured to output a clock signal according to the input signal.

9. The oscillation circuit according to claim 8, wherein the input signal is an oscillation signal of the oscillation circuit when the oscillator is connected between the first and second terminals, and is the external clock signal received via the first terminal when the oscillator is not connected between the first and second terminals.
